(19) United States
(12) Patent Application Publication
(10) Pub. No.: US 2002/0049952 A1
(43) Pub. Date: Apr. 25, 2002

(54) Method and apparatus for performing turbo decoding based on channel information

(76) Inventors: Han-Sup Lee, Seocho-Ku (KR); Tae-Geun Kim, Seocho-Ku (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/982,364

(22) Filed: Oct. 17, 2001

Related U.S. Application Data
(63) Continuation-in-part of application No. 09/739,541, filed on Dec. 15, 2000.

(30) Foreign Application Priority Data
Oct. 23, 2000 (KR) 62395-2000

(51) Int. Cl. H03M 13/00; H03M 13/03

(52) U.S. Cl. 714/786; 714/755

(57) ABSTRACT

A method and an apparatus for carrying out a turbo decoding by utilizing the channel information are disclosed. When using a turbo-decoder in a wireless communication system, in order to reduce the decoding delay, the channels are estimated by using the information such as a pilot channel information or a pilot symbol information, and the number of iterative decoding is controlled by utilizing the signal-to-interference ratio (SIR), thereby shortening the decoding delay, and making the quality of the high speed multi-media service better and reliable. The turbo code decoding apparatus utilizing a channel information according to the present invention includes a channel estimator for estimating a channel status based on reception signals to measure a SIR. Further, an iterative decoding times controller controls the number of iterative decoding by comparing the SIR with a pre-set threshold value. Further, a decoder carries out the iterative decoding as many times as controlled by the iterative decoding times controller. The present invention is applied to communication systems.

### FIELD OF THE INVENTION

The present invention relates to a method and an apparatus for performing an iterative decoding of turbo code; and, more particularly, to a method and an apparatus for controlling the number of iterative decoding of turbo code based on channel information, which reduce decoding delay and maintain the required quality of service in a wireless communication system, and a recording medium for achieving the method and apparatus.

### DESCRIPTION OF THE PRIOR ART

Generally, in the wireless communication field such as mobile communication, significant loss is occurred due to the wireless channel impairments such as propagation path loss, multi-path components and shadowing effect. The impairments cause random errors and burst errors.

In order to correct the errors such as random errors and burst errors, error correction codes are used as a method of improving the reliability.

Recently many studies are continued for applying the turbo code to the 3rd generation mobile communication (IMT-2000). The turbo code is known to have powerful performance compared with the convolutional code. The convolutional code is being currently used in the mobile communication system.

The turbo code is constituted such that the RSC (recursive systematic convolutional) codes are connected in parallel, so as to make it possible to decode through iterative decoding (which is a sub-optimal decoding method).

Further, the turbo code shows an excellent performance which approaches to the Shannon limit in case of the interleaver having a large size and sufficient iterative decoding in AWGN channel.

FIG. 1 shows the constitution of a turbo decoding scheme.

As shown in this drawing, the encoding apparatus includes: an interleaver 111˜11(n−1) for reducing the correlations by interleaving the input transmission information bits; an encoder 121 for encoding the input transmission information bits; encoders 122˜12n for encoding the interleaved signals through relevant interleavers 111˜11(n−1); and a multiplexer 130 for selectively transmitting the encoded parity bits and information bits after encoding by the encoders 121˜12n.

As shown in the drawing, the transmission information bits may be transmitted without being encoded, or may be transmitted after being encoded by the encoders 121˜12n into parity bits.

The encoded parity bits and information bits are selectively transmitted by the multiplexer 130, and therefore, it is possible to change the code rate from 1 to 1/n.

Further, in the wireless communication system, if the above described apparatus is used, its performance depends on the number of iteration. If a high quality of service (QoS) is required under sever fading channel, the number of iteration has to be increased in order to meet QoS requirement.

However, if additional information on the channels is not available for controlling the number of iteration, the decoding is carried out at the fixed number of iteration.

Under this condition, if the status of the wireless communication channels has been severely degraded, the fixed number of iteration is insufficient and the degradation of the performance cannot be avoided. On the other hand, if the channel environment is good and the signal-to-interference ratio (SIR) is high the fixed large number of iteration results in decoding delay.

### SUMMARY OF THE INVENTION

The present invention is intended to overcome the above described disadvantages of the conventional technique which is based on the fixed number of iteration.

Therefore, it is an object of the present invention to provide a method and an apparatus for carrying out a turbo decoding, and a recording medium for achieving the method and apparatus in order to reduce the decoding delay in a high SIR and maintain the required quality of service in a low SIR. The SIR is measured by the given channel information such as pilot channel or pilot symbol.

In order to reduce the decoding delay in a high SIR and maintain the required quality of service in a low SIR, the number of iteration is controlled based on the SIR, thereby shortening the decoding delay, and making the quality of the high speed multi-media service better and reliable.

To achieve the above object, in accordance with an aspect of the present invention, the turbo code decoding apparatus utilizing channel information according to the present invention includes: a channel estimator for estimating a channel status based on a signal-to-interference ratio (SIR); an iterative decoding controller for controlling the number of iterative decoding by comparing the SIR with a pre-set threshold value; and a decoder for carrying out iterative decoding as many times as controlled by the number of iterative decoding.

In accordance with another aspect of the present invention, the turbo code decoding apparatus utilizing a channel information according to the present invention includes: a channel estimator for estimating a channel status based on a signal-to-interference ratio (SIR); a power control bit generator for generating transmission power control (TPC) bits correspondingly with the SIR of the channel estimation means; an iterative decoding times controller for controlling the number of iterative decoding in accordance with the power control bits of the power control bit generating means; and a decoder for carrying out iterative decoding as many times as controlled by the number of iterative decoding.

In accordance with still another aspect of the present invention, the turbo code decoding method utilizing channel information by using a turbo code decoding apparatus according to the present invention includes the steps of: measuring a signal-to-interference ratio (SIR) by estimating a channel status based on reception signals; deciding the number of iterative decoding by comparing the SIR with a pre-set threshold value; and carrying out iterative decoding as many times as has been decided.

In accordance with still another aspect of the present invention, the turbo code decoding method utilizing channel information by using a turbo code decoding apparatus according to the present invention includes the steps of: measuring a signal-to-interference ratio (SIR) by estimating a channel status based on reception signals; generating transmission power control (TPC) bits correspondingly with the SIR measured; deciding the number of iterative decoding in accordance with the power control bits thus generated; and carrying out the iterative decoding as many times as has been decided.

In accordance with still another aspect of the present invention, there is provided a computer readable recoding media storing instructions for executing a method for performing a turbo decoding based on channel information, the method comprising the steps of: a) measuring a signal-to-interference ratio (SIR) by estimating a channel status based on reception signals; b) deciding the number of iterative decoding by comparing the SIR with a pre-set threshold value; and c) carrying out iterative decoding as many times as has been decided.

In accordance with still another aspect of the present invention, there is provided a computer readable recoding media storing instructions for executing a method for performing a turbo decoding based on channel information, the method comprising the steps of: a) measuring a signal-to-interference ratio (SIR) by estimating a channel status based on reception signals; b) generating transmission power control (TPC) bits correspondingly with the SIR measured; c) deciding the number of iterative decoding in accordance with the power control bits thus generated; and d) carrying out the iterative decoding as many times as has been decided.

### BRIEF DESCRIPTION OF THE DRAWINGS

The above objects and other advantages of the present invention will become more apparent by describing in detail the preferred embodiment of the present invention with reference to the attached drawings in which:

FIG. 1 is a block diagram showing the constitution of a turbo encoding apparatus;

FIG. 2 is a block diagram showing the constitution of the turbo decoding apparatus utilizing the channel information according to the present invention;

FIG. 3 is a flow chart showing the constitution of the turbo decoding method utilizing the channel information according to the present invention;

FIG. 4 is a block diagram showing the constitution of another embodiment of the turbo decoding apparatus utilizing the channel information according to the present invention; and

FIG. 5 is a flow chart showing the constitution of another embodiment of the turbo decoding method utilizing the channel information according to the present invention.

### DETAILED DESCRIPTION OF THE PREFERRED EMBODIMENTS

The preferred embodiments of the present invention will be described in detail referring to the attached drawings.

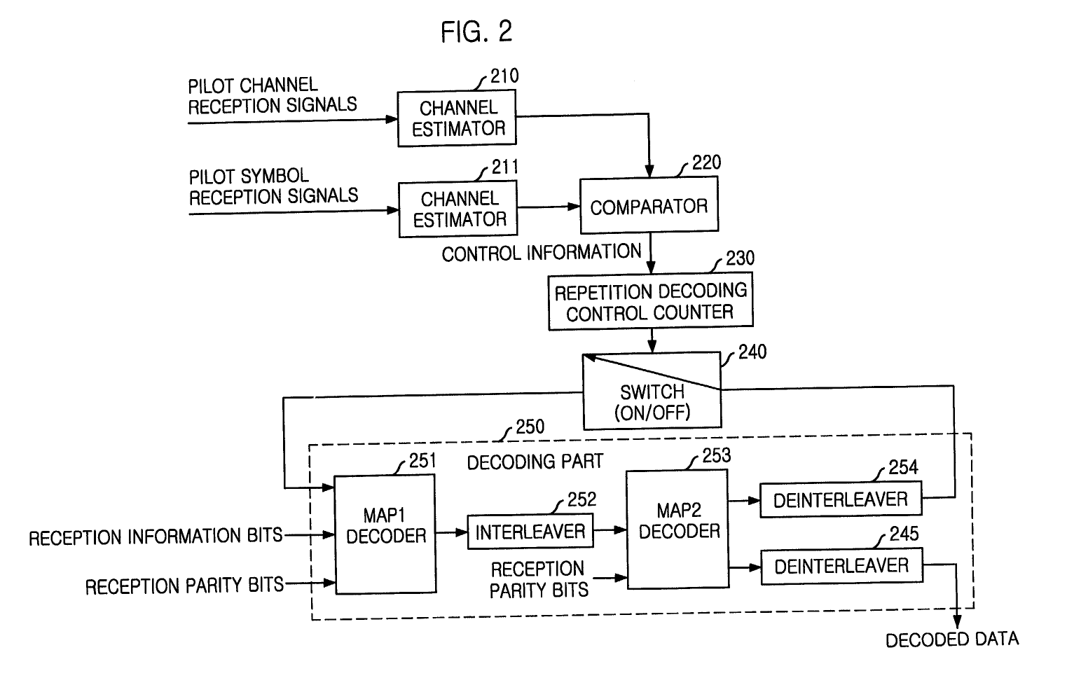

FIG. 2 is a block diagram showing the constitution of the turbo decoding apparatus utilizing the channel information according to the present invention. The signal-to-interference ratio (SIR) which has been estimated by utilizing channel information is compared with a pre-set threshold value so as to control the number of iterative decoding.

As shown in FIG. 2, the turbo decoding apparatus utilizing the channel information according to the present invention includes: channel estimators 210 and 211 for measuring the SIR by estimating the wireless channel status based on the received pilot channel signals or the received pilot symbol signals; a comparator 220 for comparing the SIR measured by the channel estimators 210 and 211 with a pre-set threshold value so as to output a control information on the number of iterative decoding; an iterative decoding control counter 230 for counting up and down the number of iterative decoding in accordance with the output value of the comparator; a switch 240 for controlling iterative decoding in accordance with the number of iterative decoding of the counter 230; and a decoding part 250 for carrying out the iterative decoding as many times as controlled by the counter 230.

The decoding part 250 includes: an MAP1 (Maximum A Posteriori 1) decoder 251; an interleaver 252; an MAP2 (Maximum A Posteriori 2) decoder 253; and deinterleavers 254 and 255.

This is a known technology, and therefore, it will not be described more here.

The turbo decoding apparatus of the present invention which is constituted as above will now be described as to its operations.

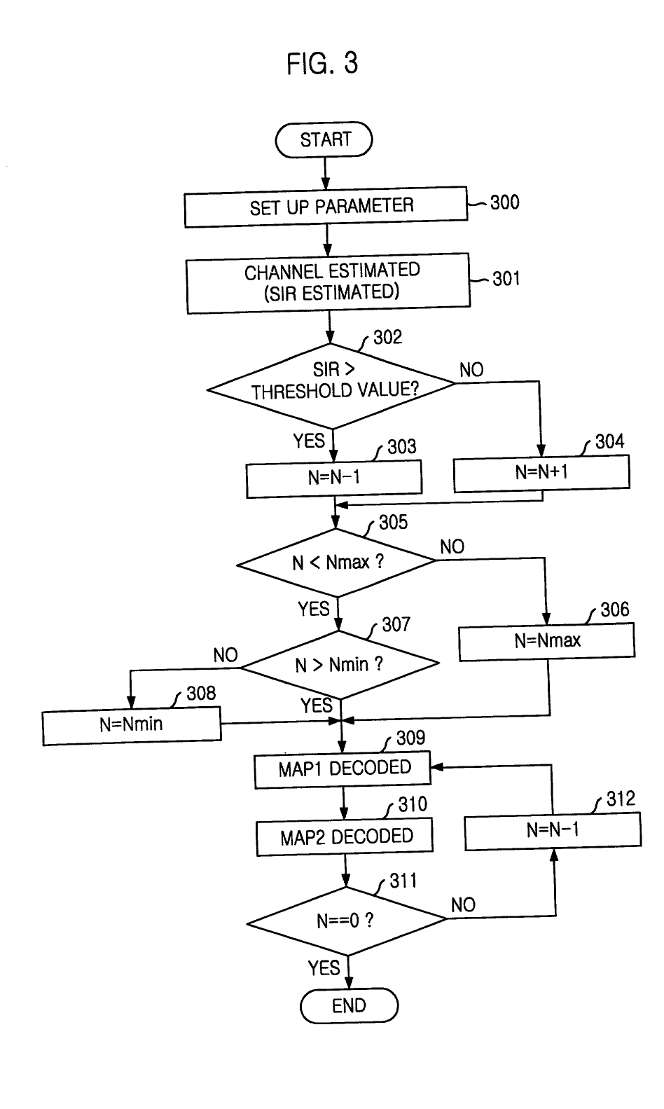

FIG. 3 is a flow chart showing the constitution of the turbo decoding method utilizing the channel information according to the present invention. Here, the SIR is applied to control the number of iterative decoding.

First, parameters are set up for controlling the number of iterative decoding for the turbo code at step 300. The parameters include the maximum number of iteration (Nmax), the minimum number of iteration (Nmin) and the threshold of the comparator, which are determined according to the required quality of service and the limited decoding delay.

Then in order to decide the number of iterative decoding, the channels are estimated using the channel estimators 210 and 211. The SIR is measured at step 301.

Then the measured signal-to-interference ratio is compared with a pre-set threshold value at step 302, and if the measured SIR is larger than the threshold value, the value N of a counter which counts the number of iterative decoding is decreased at step 303. On the other hand, if the measured SIR is smaller than the threshold value, it means the severe wireless channel environment, and therefore, the value N of the counter is increased at step 304 so as to maintain the required performance.

Then, a comparison is carried out to know as to whether the value of counter N lies in the Nmax˜Nmin range (e.g., 2˜20) for satisfying the minimum performance requisite, thereby carrying out a confirmation.

That is, at step 305, it is determined whether the adjusted counter value N is larger or smaller than the maximum number Nmax of iteration or the number of minimum number of iteration Nmin. If N is larger than Nmax, then N is fixed to Nmax at step 306, while if N is smaller than Nmax, then N is compared with Nmin to maintain the minimum performance level at step 307.

If N is found to be smaller than Nmin as a result of the comparison, then N is set to Nmin at step 308, while if N lies between Nmin and Nmax, N is fixed without variation.

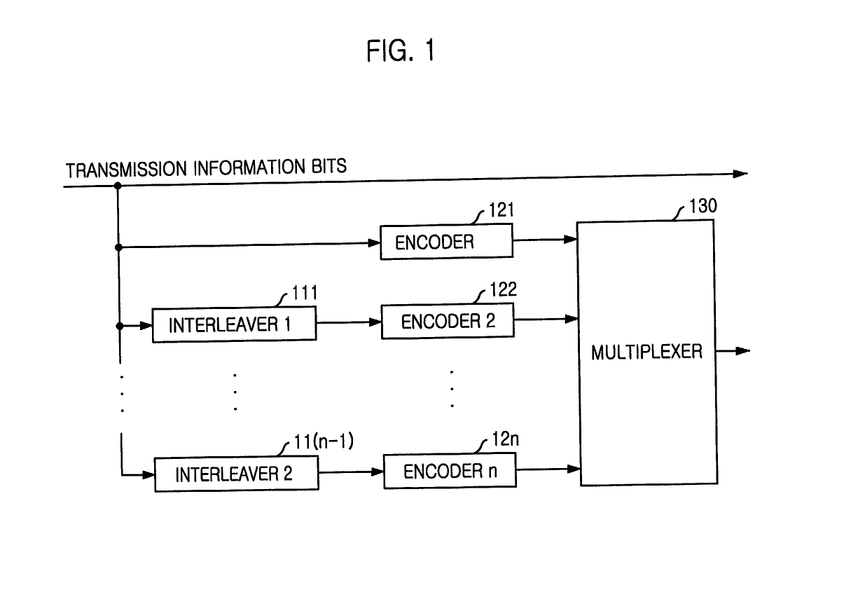

When the value of N is decided through the above described procedure, the code words which have been encoded by the encoders 1 and 2 of FIG. 1 at the transmitting end (with the code rate of ⅓) are decoded by MAP1 and MAP2 at steps 309 and 310.

Under this condition, the decoding is carried out as many times as the value N of the counter.

Each time when an iterative decoding is carried out, the value of the counter is diminished by 1 at step 312. Thus the value N is checked at step 311, and when N becomes 0, the decoding is terminated, thereby obtaining a decoded final data.

The above described procedure is carried out for each slot, or for an integer-multiple of the basic slot, or for each frame.

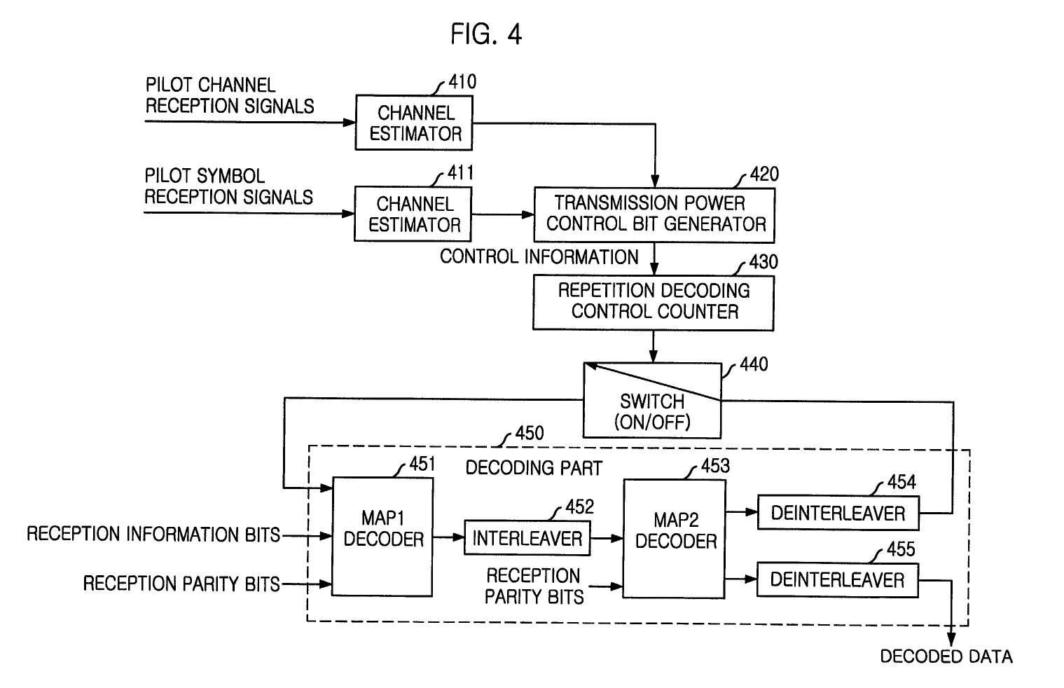

FIG. 4 is a block diagram showing the constitution of another embodiment of the decoding apparatus utilizing the channel information according to the present invention. Here, power control bits are generated correspondingly with the SIR which is obtained by utilizing the channel information, thereby controlling the number of iterative decoding.

As shown in FIG. 4, the turbo decoding apparatus based on the channel information according to the present invention includes: channel estimators 410 and 411 for measuring the SIR by estimating the channel status of the pilot channel signals or the pilot symbol signals; a transmission power control bit generator 420 for generating the transmission power control bits (TPC) correspondingly with the SIR of the channel estimators 410 and 411; an iterative decoding control counter 430 for counting the number of iterative decoding in accordance with the transmission power control bit generator 420 to output a control information on the number of iterative decoding; a switch 440 for controlling the number of iterative decoding in accordance with the value of counter 430; and a decoding part 450 for carrying out iterative decoding as many times as controlled by the switch.

The decoding part 450 includes: an MAP1 (Maximum A Posteriori 1) decoder 451; an interleaver 452; an MAP2 (Maximum A Posteriori 2) decoder 453; and deinterleavers 454 and 455.

This is a known technology, and therefore, it will not be described any more here.

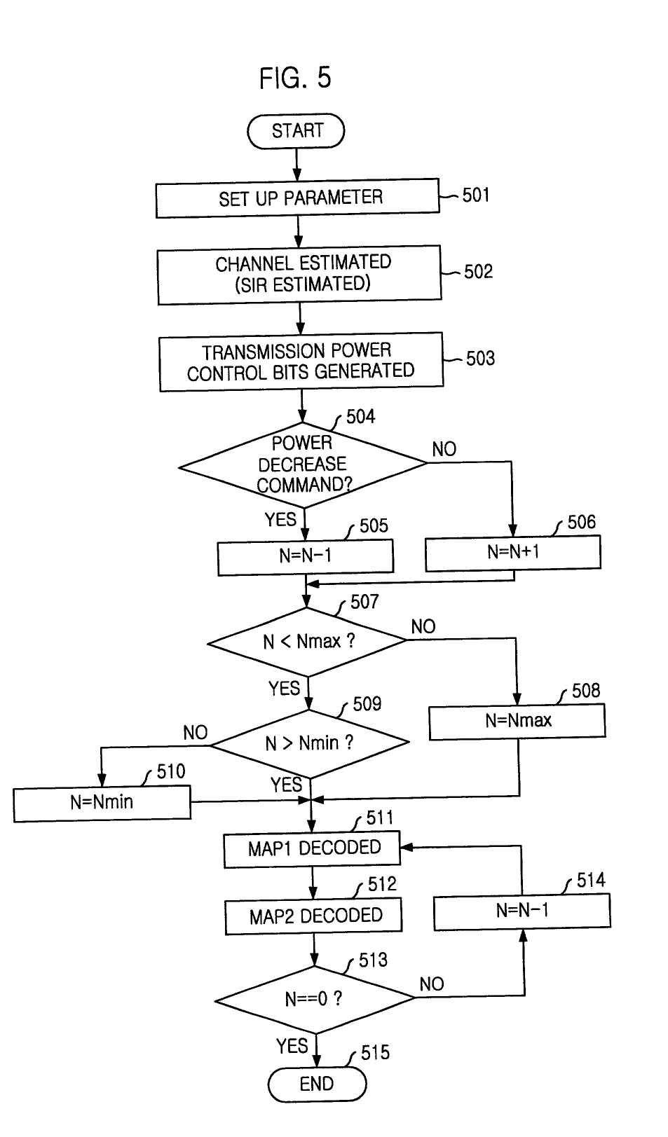

The turbo decoding apparatus of the present invention which is constituted as above will now be described as to its operations by referring to FIG. 5.

FIG. 5 is a flow chart showing the constitution of another embodiment of the turbo decoding method utilizing the channel information according to the present invention. Here, power control bits are generated to control the number of iterative decoding for turbo code having a code rate of ⅓.

First, parameters are set up for controlling the number of iterative decoding for the turbo code at step 501.

The parameters include the maximum number of iteration (Nmax), the minimum number of iteration (Nmin) and the threshold of the comparator, which are determined according to the required quality of service and the limited decoding delay.

Then, in order to control the number of iterative decoding, the pilot channel information or the pilot symbol information is utilized to estimate the channel so as to obtain the SIR at step 502. Then TPC (transmission power control) bits are generated correspondingly with the measured SIR at step 503.

Then a checking is carried out as to whether a power decrease command is inputted from the terminal to the base station or from the base station to the terminal at step 504.

Upon the checking, if it is found that a power increase command has been inputted from the terminal to the base station or from the base station to the terminal, then a closed loop power control is carried out, and the number of iterative decoding of the turbo decoder is increased in accordance with the power increase command at step 506.

Upon the checking, on the contrary, if it is found that a power decrease command has been inputted, then the number of iterative decoding is decreased at step 505.

The value of N which has been decided by the power control bits is subjected to a checking as to whether the minimum service quality requisite (value of Nmin) and the delay limitation (value of Nmax) is satisfied at steps 507 to 510.

That is, the adjusted value N of the counter is compared with the maximum repetition value Nmax at step 507, and if N is larger than Nmax, then N is fixed to Nmax at step 508. On the other hand, if N is smaller than Nmax, N is compared with Nmin which is the minimum repetition times at step 509.

Upon comparing N with Nmin, if it is found that N is smaller than Nmin, then N is set to Nmin at step 510, while if N lies between Nmin and Nmax, then N is kept as it is.

When N is decided through the above described procedure, the code words which have been encoded at the transmission end of FIG. 1 by the encoders 1 and 2 having a code rate of ⅓ are decoded by MAP1 and MAP2 at steps 511 and 512. Under this condition, the decoding is carried out as many times as N which has been decided through the above described procedure.

Each time when an iterative decoding is carried out, the counter value is diminished by 1 at step 514, and checking is carried out on the value of N. Ultimately, when the value of N becomes zero, the decoding is terminated, thereby obtaining the finally decoded data.

The above described procedure is carried out for each slot, or for an integer-multiple of the basic slot, or for each frame.

Meanwhile, the method of estimating the optimum channel can be different depending on the pilot structure which is used. However, in the general pilot channels and the general pilot symbols, the estimation can be carried out by utilizing a moving average filter.

According to the present invention as described above, the channel information which is given in the wireless communication system is utilized so as to efficiently control the number of iterative decoding for the turbo code. Thus the problem of the decoding delay can be solved in a high SIR by reducing the number of iteration keeping the required performance and also it is possible to afford a required quality service in a low SIR by increasing the number of iteration within the range of iteration (Nmin˜Nmax).

Further, as the decoding delay time is shortened, the power consumption can be saved, and therefore, the overall capacity of the system can be expanded.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An apparatus for performing a turbo decoding based on channel information, comprising:
a channel estimation means for estimating a channel status based on reception signals to measure a signal-to-interference ratio (SIR);
an iterative decoding times control means for controlling a number of iterative decoding by comparing the SIR with a pre-set threshold value; and
a decoding means for carrying out iterative decoding as many times as controlled by said iterative decoding times control means.

2. The apparatus as recited in claim 1, wherein said iterative decoding times control means includes:
an iterative decoding times deciding means for comparing the SIR of said channel estimation means with a threshold value to increase or decrease the number of iterative decoding, and for comparing the iterative decoding times with the minimum number of iteration and the maximum number of iteration to decide the iterative decoding times.

3. An apparatus for performing a turbo decoding based on channel information, comprising:
a channel estimation means for estimating a channel status based on reception signals to measure a signal-to-interference ratio (SIR);
a power control bit generating means for generating transmission power control (TPC) bits correspondingly with the SIR of said channel estimation means;
an iterative decoding times control means for controlling a number of iterative decoding in accordance with the power control bits of said power control bit generating means; and
a decoding means for carrying out the iterative decoding as many times as controlled by said iterative decoding times control means.

4. The apparatus as recited in claim 3, wherein said iterative decoding times control means includes:
an iterative decoding times deciding means for increasing/decreasing the number of iterative decoding in accordance with power increase/decrease commands based on the power control bits of said power control bit generating means to increase/decrease the number of iterative decoding, and for comparing the number of iterative decoding with the minimum number of iteration and the maximum number of iteration to decide the number of iterative decoding.

5. A method for performing a turbo decoding based on channel information, comprising the steps of:
a) measuring a signal-to-interference ratio (SIR) by estimating a channel status based on reception signals;
b) deciding a number of iterative decoding by comparing the SIR with a pre-set threshold value; and
c) carrying out iterative decoding as many times as has been decided.

6. The method as recited in claim 5, wherein the step b) includes the steps of:
b1) comparing the SIR with the pre-set threshold value to increase/decrease the number of iterative decoding; and
b2) comparing the increased/decreased number of iterative decoding with the minimum number of iteration and the maximum number of iteration to decide the number of iterative decoding.

7. A method for performing a turbo decoding based on channel information, comprising the steps of:
a) measuring a signal interference ratio (SIR) by estimating a channel status based on reception signals;
b) generating transmission power control bits (TPC) correspondingly with the SIR measured;
c) deciding a number of iterative decoding in accordance with the power control bits thus generated; and
d) carrying out the iterative decoding as many times as has been decided.

8. The method as recited in claim 7, wherein the step c) includes the steps of:
c1) increasing/decreasing the number of iterative decoding in accordance with a power increase/decrease command based on values of the power control bits; and
c2) comparing the number of the increased/decreased iterative decoding with the minimum number of iteration and the maximum number of iteration to decide the number of iterative decoding.

9. A computer readable recoding media storing instructions for executing a method for performing a turbo decoding based on channel information, the method comprising the steps of:
a) measuring a signal-to-interference ratio (SIR) by estimating a channel status based on reception signals;
b) deciding a number of iterative decoding by comparing the SIR with a pre-set threshold value; and
c) carrying out iterative decoding as many times as has been decided.

10. A computer readable recoding media storing instructions for executing a method for performing a turbo decoding based on channel information, the method comprising the steps of:
a) measuring a signal-to-interference ratio (SIR) by estimating a channel status based on reception signals;
b) generating transmission power control bits (TPC) correspondingly with the SIR measured;
c) deciding a number of iterative decoding in accordance with the power control bits thus generated; and
d) carrying out the iterative decoding as many times as has been decided.
